(19) United States
(12) Patent Application Publication
(10) Pub. No.: US 2008/0087977 A1
(43) Pub. Date: Apr. 17, 2008

(54) SOLID-STATE IMAGING DEVICE AND METHOD OF MANUFACTURING THE SAME

(75) Inventor: Shinya Watanabe, Kumamoto (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 11/756,163

(22) Filed: May 31, 2007

(30) Foreign Application Priority Data
Jun. 8, 2006 (JP) 2006-160001

(51) Int. Cl. H01L 31/0224; H01L 31/18

(52) U.S. Cl. 257/459; 438/98; 257/E31.125

(57) ABSTRACT

The present invention provides a solid-state imaging device having an element isolation layer that is formed by embedding a conductive material into a trench-processed groove portion provided in a semiconductor base, in which a predetermined voltage is applied to the element isolation layer.

### CROSS REFERENCES TO RELATED APPLICATIONS

The present invention contains subject matter related to Japanese Patent Application JP 2006-160001 filed in the Japanese Patent Office on Jun. 8, 2006, the entire contents of which being incorporated herein by reference.

### BACKGROUND OF THE INVENTION

1. Field of the Invention

The present invention relates to a solid-state imaging device and a method of manufacturing the same. Particularly, the invention is directed to a solid-state imaging device having a structure in which a sensor portion extends to a deep position of a semiconductor base, and a method of manufacturing the same.

2. Description of Related Art

Recently, along with a call for smaller, lighter and lower-power-consumption products using a solid-state imaging device, processing circuitry provided in a signal processing element has also been formed around a light-receiving portion of the solid-state imaging device, to allow all the processing to be performed by a single solid-state imaging device and hence to eliminate the signal processing element.

As such a solid-state imaging device, it is particularly known that a Complementary Metal Oxide Semiconductor (CMOS) type solid-state imaging device is advantageous in realizing smaller, lighter, lower-cost and further lower-power-consumption products. Thus, peripheral circuitry including predetermined circuits has been formed around the light-receiving portion in which CMOS-structured photoelectric conversion elements are formed, to form a single solid-state imaging device.

Additionally, along with the progress of the miniaturization technology for the MOS process, photoelectric conversion elements smaller is size and having more-pixels can be achieved easily for the, and higher-density peripheral circuitry is also realizable, thus leading the CMOS solid-state imaging device technology toward further smaller, more-pixel and higher-function implementations.

As an example of the recent miniaturization technology, a Shallow Trench Isolation (STI) technology, for example, is used for isolation of the photoelectric conversion elements. By reducing the area of an element isolation portion while ensuring the element isolation capability, and further by ensuring the area of the light-receiving portion, products with more pixels and a reduced chip area have already been commercialized, with the imaging performance maintained, despite reduction in the cell size.

By the way, as the latest technological trend, a technology for forming an N-type region that becomes a sensor portion, at a depth of a few microns from the surface has been applied in order to enhance the sensitivity. In line therewith, in forming an impurity region that becomes an overflow barrier region, or specifically, in doping a P-type impurity, for example, by ion implantation, a high-energy ion implantation technology has been adopted.

Furthermore, where the above-mentioned sensor portion and overflow barrier region are to be formed at a deep position, a channel stop region for isolation of pixels is also to be formed at a deep position. That is, in order to suppress occurrence of so-called “blooming” and “mixed color” in which electrons photoelectrically converted at the sensor portion leak into adjacent pixels, the channel stop region also needs to be formed at a deep position.

Meanwhile, the above-mentioned STI technology is to isolate devices at a depth of a few hundred nanometers, and thus is suitable for element isolation on the side of the silicon substrate surface. However, for element isolation at a depth of a few microns, the STI technology alone is not enough. Thus, an impurity has been doped to form the channel stop region, to implement element isolation.

A method of manufacturing a related art CMOS solid-state imaging device to which the STI technology is applied will be described below with reference to the drawings.

In the method of manufacturing the related art CMOS solid-state imaging device, first, a silicon nitride film 102, for example, is formed on an N-type silicon substrate 101 by a low-pressure CVD method so as to cover the entire surface of the silicon substrate, and then general-purpose photolithography and etching technologies are used to form a trench (groove portion) 104 for element isolation (see FIG. 4A).

Next, the trench is filled with an insulating film 105 such as a CVD oxide film, for example (see FIG. 4B), and then the entire surface of the silicon substrate is polished using a Chemical Mechanical Polishing (CMP) technology. Thereafter, the silicon nitride film is selectively removed using phosphoric acid, for example, so that an element isolation layer 106 such as shown in FIG. 4C can be obtained.

Successively, a P-type impurity is selectively doped using general-purpose photolithography and ion implantation technologies to form a channel stop region 107. Moreover, ions are selectively implanted using the general-purpose photolithography and ion implantation technologies to form an overflow barrier region 109.

Thereafter, an N-type impurity is selectively doped into a portion that becomes a light-receiving region of the imaging device using the general-purpose photolithography and ion implantation technologies to form a light-receiving region 108 being the sensor portion, thus, a CMOS solid-state imaging device such as shown in FIG. 4D can be obtained.

By applying the STI technology as mentioned above, a CMOS solid-state imaging device having an element isolation layer formed therein can be obtained. However, as mentioned above, the isolation depth based on the STI technology is only about a few hundred nanometers. When the N-type region for forming the sensor portion is to be formed at a depth of a few microns from the surface in order to enhance the sensitivity, the channel stop region is also required to be formed at a deep position similarly to the sensor portion. To meet such a requirement, in the method of manufacturing the conventional CMOS solid-state imaging device, a photoresist mask has been formed using the general-purpose lithography technology, and the channel stop region has been formed using the general-purpose ion implantation technology, as mentioned above. However, when the photoresist mask is to be formed using the general-purpose lithography technology and then the channel stop region is to be formed as deep as a few microns from the surface using the general-purpose ion implantation technology, a thick photoresist mask must be formed, thus making it difficult to achieve miniaturization.

That is, if the channel stop region is formed in a deeper region, high-energy ion implantation is to be performed. If high-energy ion implantation is performed using a photoresist mask, the thickness of the photoresist mask on the order of a few microns is required under the present situation. Thus, in terms of the limit of miniaturization, the width of the channel stop region would be on the order of a little less than 1.0 μm. Therefore, it is difficult to implement a narrower width (e.g., 0.5 μm or less) of the channel stop region, thus making it impossible to follow miniaturization of the solid-state imaging device.

To overcome this situation, a method has recently been proposed in which an insulator is used to fill a trench-processed groove to physically isolate pixel regions (e.g., see Japanese Patent Application Publication No. 2002-57318).

### SUMMARY OF THE INVENTION

However, an element isolation layer formed of an insulator filling the trench-processed groove causes many interface states on the internal wall as well as the bottom surface of the trench due to etching, easily causing image quality degradation (so-called abnormal output values due to white spot defects, dark current and the like).

The present invention has been made in view of the above and other problems, and provides a solid-state imaging device capable of implementing miniaturization and also of suppressing image quality degradation, and a method of manufacturing the same.

A solid-state imaging device according to an embodiment of the present invention is a solid-state imaging device having an element isolation layer that is formed of a conductive material filling a trench-processed groove portion provided in a semiconductor base. A predetermined voltage is applied to the element isolation layer.

Here, by applying the predetermined voltage to the element isolation layer, electrons that would cause white spot defects and dark current can be fixed by the element isolation layer, and thus image quality degradation can be suppressed. Furthermore, where a P-type impurity is contained in the conductive material filling the groove portion, the spreading of a depletion layer to the interface of the element isolation layer having crystal defects can be suppressed, which results in suppressing occurrence of white spots and dark current. Note that if a negative voltage is applied to the element isolation layer, the electrons can be fixed more effectively.

Furthermore, a method of manufacturing a solid-state imaging device according to an embodiment of the present invention includes the steps of: forming a groove portion by forming a trench in a semiconductor base; forming an element isolation layer by filling the groove portion with a conductive material; forming a sensor portion in a region that is isolated by the element isolation layer; and forming an interconnection layer through which a predetermined voltage is applied to the element isolation layer.

Here, since the interconnection layer for applying a predetermined voltage to the element isolation layer is formed, the predetermined voltage can be applied to the element isolation layer through the interconnection layer, to allow the element isolation layer to fix electrons that would cause white spots and dark current. Consequently, image quality degradation can be suppressed. Furthermore, if a P-type impurity is contained in the conductive material filling the groove portion, the spreading of a depletion layer to the interface of the element isolation layer having crystal defects is suppressed, and occurrence of white spots and dark current can be suppressed. Note that where a negative voltage is applied to the element isolation layer, the electrons can be fixed more effectively.

### BRIEF DESCRIPTION OF THE DRAWINGS

FIG. 1 is a schematic sectional view for illustrating an element isolation layer in a CMOS solid-state imaging device being an example of a solid-state imaging device to which the present invention is applied;

FIGS. 2A to 2C are schematic sectional views for illustrating a method of manufacturing a CMOS solid-state imaging device being an example of a method of manufacturing the solid-state imaging device to which the present invention is applied;

FIGS. 3A to 3C are schematic sectional views showing the steps continuing from FIG. 2C for illustrating the method of manufacturing a CMOS solid-state imaging device being the example of the method of manufacturing the solid-state imaging device to which the present invention is applied; and

FIGS. 4A to 4D are schematic sectional views for illustrating a method of manufacturing a related art CMOS solid-state imaging device.

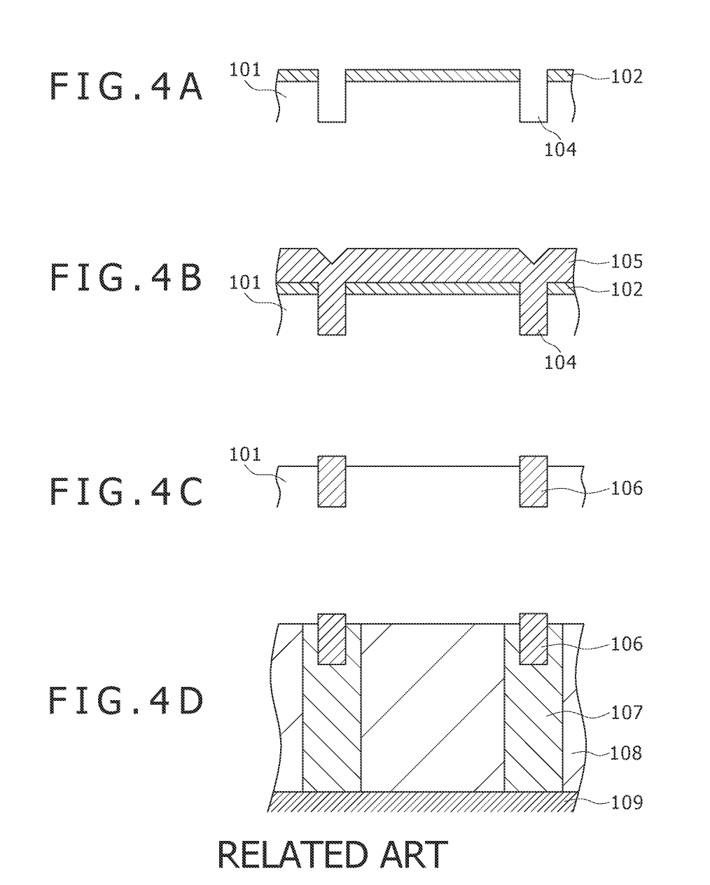

### DESCRIPTION OF THE EMBODIMENTS

Embodiments of the present invention will be described below with reference to the drawings, for an understanding of the present invention.

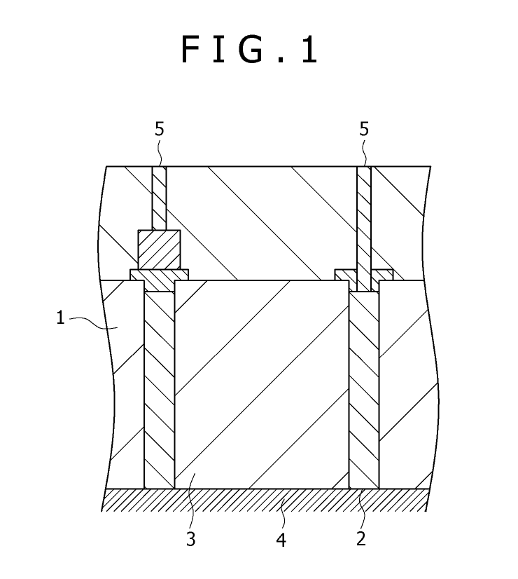

FIG. 1 is a schematic sectional view for illustrating an element isolation layer in a CMOS solid-state imaging device being an example of a solid-state imaging device to which the present invention is applied. In the CMOS solid-state imaging device herein shown, amorphous silicon containing B (boron) fills a trench-processed groove portion in an N-type silicon substrate 1 to form an element isolation layer 2. Furthermore, a light-receiving region 3 is formed in a region isolated by the element isolation layer, and also an overflow barrier region 4 is formed deep inside the N-type silicon substrate. Furthermore, an interconnection layer 5 is connected to the element isolation layer, and it is configured such that a negative voltage can be applied to the element isolation layer.

In FIG. 1, the trench structure on the left shows a case of applying the negative voltage to the element isolation layer 2 from the interconnection layer 5 via a gate, while the trench structure on the right shows a case of applying the negative voltage to the element isolation layer 2 directly from the interconnection without using the gate.

Note that the N-type silicon substrate herein shown is an example of a semiconductor base, and that the amorphous silicon is an example of a conductive material, and further that boron is an example of a P-type impurity.

While a case where boron-containing amorphous silicon fills a groove portion to form an element isolation layer is described as an example in the present embodiment, it suffices that a material filling the groove portion is a conductive material, not necessarily a material containing a P-type impurity (boron in the present embodiment). That is, since a predetermined voltage is applied to the element isolation layer to fix electrons to suppress image quality degradation, it is required that the material for filling the groove portion be conductive, but does not necessarily contain a P-type impurity. However, if the conductive material for filling the groove portion contains a P-type impurity, the spreading of a depletion layer to the interface of the element isolation layer having crystal defects can be suppressed, and thus, occurrence of white spots and dark current is suppressed, and thus it could implement further suppression of image quality degradation. Consequently, it would be preferable to fill the groove portion with a conductive material containing a P-type impurity.

A method of manufacturing the thus configured CMOS solid-state imaging device will be described below. That is, a method of manufacturing a CMOS solid-state imaging device being an example of a method of manufacturing the solid-state imaging device to which the present invention is applied will be described.

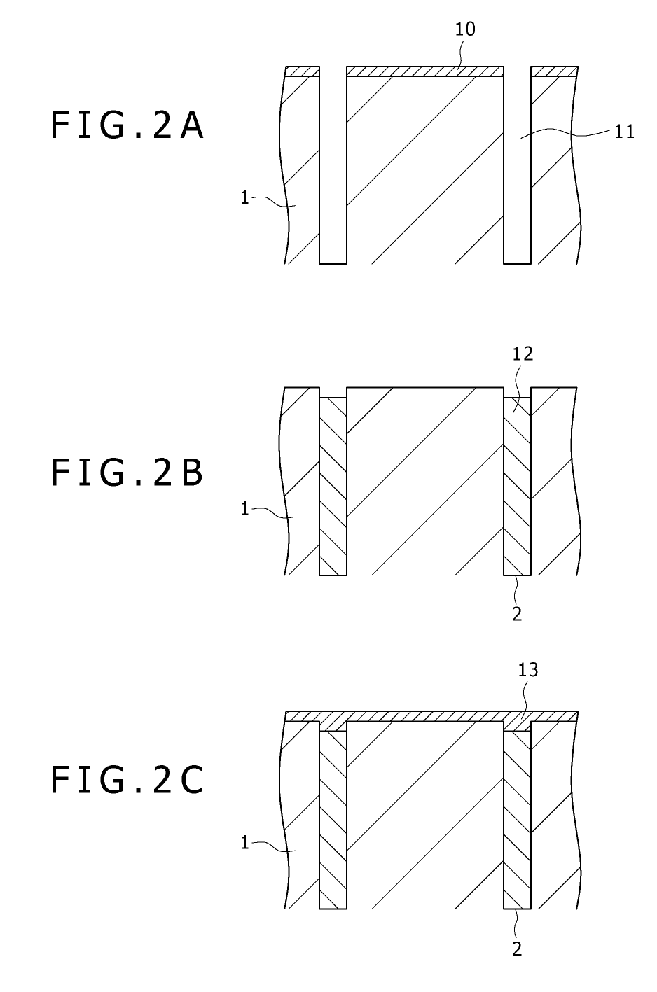

In the method of manufacturing a CMOS solid-state imaging device to which the present invention is applied, first, a thermal oxide film 10, for example, is formed on an N-type silicon substrate 1 so as to cover the entire surface of the silicon substrate, and then the general-purpose photolithography and etching technologies are used to form a trench (groove portion) 11 for element isolation (see FIG. 2A).

Next, the trench is filled with boron-containing amorphous silicon 12. Then, using an entire etch back method based on the general-purpose etching technology, a film of amorphous silicon formed on the entire surface of the N-type silicon substrate is removed. Thereafter, the thermal oxide film is removed by wet etching or the like, whereby the trench-processed element isolation layer 2 such as shown in FIG. 2B can be formed. Here, the amorphous silicon is entirely etched back, and thus the upper part of the trench is recessed in shape.

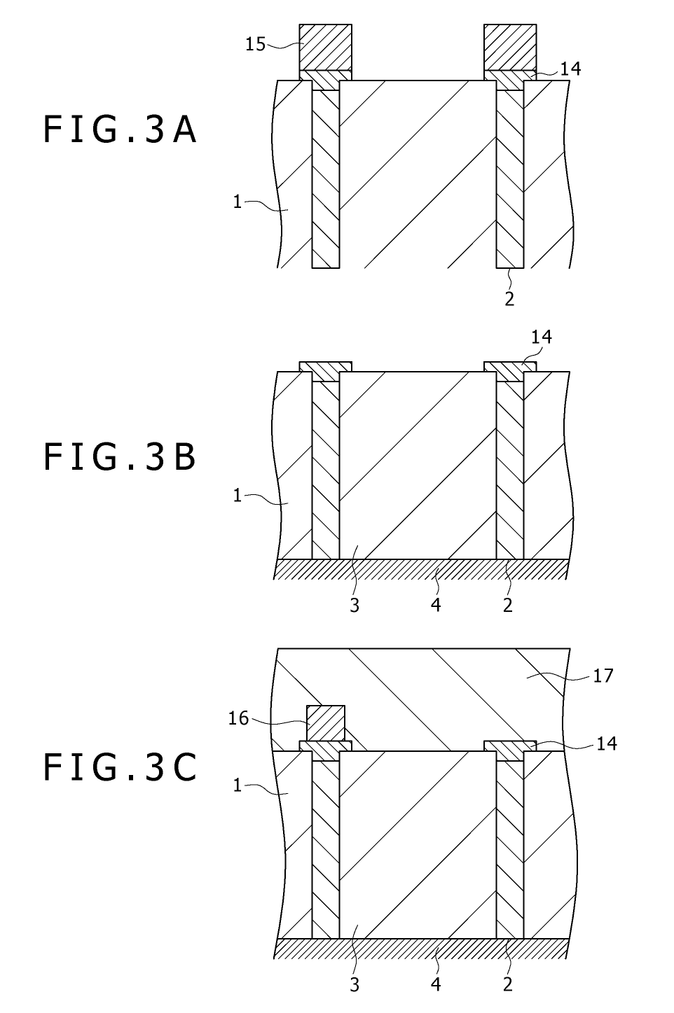

Successively, a CVD oxide film 13 or the like, for example, is formed on the N-type silicon substrate so as to cover the entire surface of the N-type silicon substrate (see FIG. 2C), and then using the general-purpose photolithography and etching technologies, a buffer film 14 is formed, which isolates the trench serving as the element isolation layer from a gate electrode to be formed in a subsequent process (see FIG. 3A).

Thereafter, a photoresist 15 is removed and an N-type impurity is selectively doped into portions that become the overflow barrier region and the light-receiving region of the imaging device using the general-purpose photolithography and ion implantation technologies, respectively, and thus, the overflow barrier region 4 and the light-receiving region 3 are formed (see FIG. 3B).

Furthermore, after a gate electrode 16 is formed on the buffer film, an inter-layer insulating film 17 for forming the interconnection layer is formed, and then a planarization process is performed by the CMP technology (see FIG. 3C). Next, a connecting hole for connecting the gate electrode, the element isolation layer and the interconnection layer is formed, and the connecting hole is then filled with titanium (Ti), titanium nitride (TiN), tungsten or the like, and further planarized by the CMP technology. Thereafter, normal interconnection layers, and a film between the interconnection layers are formed whenever necessary, whereby a desired CMOS solid-state imaging device can be obtained (see FIG. 1).

In the CMOS solid-state imaging device to which the present invention is applied, an element isolation layer in which a trench is filled with amorphous silicon is formed, and also a negative voltage supplied from inside or outside the CMOS solid-state imaging device is applied to the element isolation layer. Accordingly, electrons causing interface states, white spot defects and dark current can be fixed at the trench-processed element isolation layer, resulting in preventing image quality degradation such as white spot defects.

Furthermore, since the amorphous silicon film for filling the trench is formed at a low pressure, even a deeper trench can be filled easily, and it is possible to satisfactorily form a deeper trench-processed element isolation layer, thus enabling sufficiently suppressing leakage of electrons into adjacent pixels.

In the above-mentioned solid-state imaging device and method of manufacturing the same according to the embodiments of the present invention, even if the technology is applied which physically isolates pixel regions by forming trenches in the semiconductor base to form the element isolation layer, the so-called abnormal output values due to white spot defects, dark current and the like can be suppressed, and thus can achieve miniaturization and suppress image quality degradation.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging device having an element isolation layer that is formed of a conductive material filling a trench-processed groove portion provided in a semiconductor base, wherein:
a predetermined voltage is applied to the element isolation layer.

2. The solid-state imaging device according to claim 1, wherein:
the conductive material contains a P-type impurity.

3. The solid-state imaging device according to claim 1, wherein:
the predetermined voltage is a negative voltage.

4. A method of manufacturing a solid-state imaging device comprising the steps of:
forming a groove portion by forming a trench in a semiconductor base;
forming an element isolation layer by filling the groove portion with a conductive material;
forming a sensor portion in a region that is isolated by the element isolation layer; and
forming an interconnection layer through which a predetermined voltage is applied to the element isolation layer.

5. The method of manufacturing a solid-state imaging device according to claim 4, wherein:
the conductive material contains a P-type impurity.

6. The method of manufacturing a solid-state imaging device according to claim 4, wherein:
the predetermined voltage is a negative voltage.
